(19) United States
(12) Patent Application Publication
(10) Pub. No.: US 2008/0313517 A1
(43) Pub. Date: Dec. 18, 2008

(54) DEBUG CIRCUIT

(76) Inventors: Yasushi UEDA, Saijo-shi (JP); Makoto Okazaki, Niihama-shi (JP)

Correspondence Address: WENDEROTH, LIND & PONACK L.L.P., 2033 K. STREET, NW, SUITE 800, WASHINGTON, DC, 20006, US

(21) Appl. No.: 12/194,698

(22) Filed: Aug. 20, 2008

Related U.S. Application Data
(62) Division of application No. 10/939,406, filed on Sep. 14, 2004.

(30) Foreign Application Priority Data
Sep. 19, 2003 (JP) 2003-328803

(51) Int. Cl. G01R 31/3183; G06F 11/263

(52) U.S. Cl. 714/744; 714/E11.177

(57) ABSTRACT

The present invention provide a debug circuit which has a structure in which a conversion block latches plural internal signals which are supposed to be effective in finding a cause of a malfunction and are outputted from a selection block, using a signal that is outputted from a timing generation block, converts these signals into serial data, and outputs the serial data to an output block, thereby observing plural signals in the LSI using fewer external pins, and performing analysis of the malfunction of the LSI speedy and reliably.

This is a Rule 1.53(b) Divisional of application Ser. No. 10/939,406, filed Sep. 14, 2004.

### FIELD OF THE INVENTION

The present invention relates to debug circuits and, more particularly, to circuits for debugging timing of a logic circuit in an LSI (large-scale integrated circuit) at a malfunction of the logic circuit in the LSI.

### BACKGROUND OF THE INVENTION

An LSI is usually formed by integrating so many circuits at high density. Therefore, at the designing state and the prototyping stage, it is required to ensure not only proper operations of the respective circuits but also mutual operations among these circuits. Particularly, since signal channels for these circuits inevitably involve a propagation delay or the like, the LSI may cause an abnormality in the operation (malfunction) resulting from variations in signal timing.

When a malfunction occurs, debugging is performed and the cause of the malfunction is investigated to solve the problem. In a conventional technique for debugging a malfunction of the LSI, the internal condition of the LSI is estimated on the basis of limited information that is obtained from a procedure of the program and a waveform observation of the external terminal of the LSI using a measuring device, such as a logic analyzer, and it is judged whether the estimated condition logically falls within design data or not.

Further, for example, Japanese Published Patent Application No. 2000-259441 (pp. 1-4, FIG. 1) suggests a circuit which enables to directly observe a desired signal through an external terminal by previously inputting an internal timing signal of the LSI into plural selection circuits and decoding a register value which is obtained by register setting from outside the LSI to be inputted to the plural selection circuits.

However, in the former example of the prior art, because the internal condition of the LSI must be estimated or assumed on the basis of the limited information, it takes much time to investigate the cause of the malfunction of the LSI. In the latter case, since the signal in the LSI is directly outputted outside, many special external pins are required to analyze the cause of the malfunction. Further, as many of the internal timing signals operate at high speeds, measuring devices adapted to their speeds are needed to observe the signals from outside the LSI. Furthermore, there are some cases where it is impossible to generate a trigger for starting the analysis of the problem on the basis of the internal timing signal by itself.

### SUMMARY OF THE INVENTION

The present invention has for its object to provide a debug circuit which includes a register that is rewritable by a selection circuit and from outside the LSI, and can observe plural conditions in the LSI using fewer external pins, by efficiently selecting parallel signals within a logic circuit and converting these signals into a serial signal.

Another object of the present invention is to provide a debug circuit that can generate, at the time of analysis, a trigger signal of a timing which is not supposed at the designing stage, by performing an arithmetic operation to the selected internal signal in the logic circuit and outputting the data.

A further object of the present invention is to provide a debug circuit which can relatively easily capture a signal changing at high speed and observe the same, by detecting a transition point of the selected high-speed signal in the logic circuit to invert the signal or change the pulse width of the signal.

A still further object of the present invention is to provide a debug circuit that enables to perform an analysis of abnormal data in the LSI using fewer external pins, by comparing a selected internal signal of the logic circuit with a value that is set in a register and outputting the result of the comparison to outside the LSI.

Other objects and advantages of the invention will become apparent from the detailed description that follows. The detailed description and specific embodiments described are provided only for illustration since various additions and modifications within the spirit and scope of the invention will be apparent to those of skill in the art from the detailed description.

According to a 1st aspect of the present invention, there is provided a debug circuit that debugs functions of an LSI including a logic circuit which implements desired logic functions, comprising: a selection block for selecting predetermined signals from plural timing or condition signals that are outputted from the logic circuit; a timing generation block for selecting a predetermined reference signal from among plural reference signals that are outputted from the logic circuit; a conversion block for parallel/serial converting the predetermined signals that are selected in the selection block in a timing of the reference signal that is outputted from the timing generation block, and outputting a serial signal; and an output block for outputting the serial signal that is outputted from the conversion block to the outside. Therefore, it is possible to efficiently select plural internal timing signals, condition signals, or reference signals of the logic circuit to improve an efficiency at the debugging, and perform the parallel/serial conversion to observe many internal signals in the logic circuit using fewer external pins.

According to a 2nd aspect of the present invention, there is provided a debug circuit that debugs functions of an LSI including a logic circuit which implements desired logic functions, comprising: a selection block for selecting predetermined signals from among plural timing or condition signals which are outputted from the logic circuit; a trigger signal generation block for performing a logical operation to the predetermined signals which are selected in the selection block, and outputting a result of the operation as a trigger signal; and an output block for outputting the predetermined signals that are selected in the selection block and the trigger signal to outside. Therefore, a trigger signal of a timing, which is not previously supposed at the designing stage, can be easily generated when it is needed at the debugging.

According to a 3rd aspect of the present invention, there is provided a debug circuit that debugs functions of an LSI including a logic circuit which implements desired logic functions, comprising: a selection block for selecting predetermined signals from among plural timing or condition signals which are outputted from the logic circuit; a transition point inverting block for detecting transition points of the respective predetermined signals which are selected in the selection block, and inverting the predetermined signals at the detected transition points; and an output block for outputting the predetermined signals that are inverted by the transition point inverting block to outside. Therefore, it is possible to relatively easily capture signals that change at high speeds to observe also the high-speed signals, whereby it is possible to greatly improve the debug efficiency.

According to a 4th aspect of the present invention, there is provided a debug circuit that debugs functions of an LSI including a logic circuit which implements desired logic functions, comprising: a selection block for selecting predetermined signals from plural timing or condition signals which are outputted from the logic circuit; a pulse-width changing block for detecting transition points of the respective predetermined signals which are selected in the selection block, and changing a pulse width of the respective predetermined signals at the detected transition points; and an output block for outputting the predetermined signals that are converted in the pulse-width changing block to outside. Therefore, it is possible to relatively easily capture signals that change at high speeds to observe also the high-speed signals, whereby it is possible to greatly improve the debug efficiency.

According to a 5th aspect of the present invention, there is provided a debug circuit that debugs functions of an LSI including a logic circuit which implements desired logic functions, comprising: a selection block for selecting predetermined signals from among plural timing or condition signals which are outputted from the logic circuit; a signal level judging block for judging levels of the predetermined signals which are selected in the selection block, and outputting a result of the judgement; and an output block for outputting the predetermined signals which are selected in the selection block and the result of the level judgement, to outside. Therefore, it is possible to detect abnormal conditions of plural signals on a bus such as a data bus or an address bus in the LSI, using quite a few output terminal, and also possible to freely change a comparison reference value by changing the value of the register, even when the LSI is operating, whereby it is possible to further enhance the debug efficiency.

According to the present invention, it is possible to check the internal timing or internal condition that is outputted from the internal circuit of the LSI which is mounted on a target apparatus, from outside the LSI and, at the evaluation of the apparatus, quickly find omission of the debugging during logical simulation at the verification in the LSI designing. Thereby, it is possible to reduce the number of steps for evaluating the LSI, and shorten the developing time which is required to develop the LSI. It is also possible to analyze a potential bug that is not detected at the evaluation of the LSI and may occur in the practical use environments

### BRIEF DESCRIPTION OF THE DRAWINGS

FIG. 1 is a block diagram illustrating a structure of a debug circuit according to a first embodiment of the present invention.

FIG. 2 is a block diagram illustrating a structure of a debug circuit according to a second embodiment of the present invention.

FIG. 3 is a block diagram illustrating a structure of a debug circuit according to a third embodiment of the present invention.

FIG. 4 is a block diagram illustrating a structure of a debug circuit according to a fourth embodiment of the present invention.

FIG. 5 is a block diagram illustrating a structure of a debug circuit according to a fifth embodiment of the present invention.

### DETAILED DESCRIPTION OF THE PREFERRED EMBODIMENTS

Hereinafter, embodiments of the present invention will be described in detail with reference to the drawings.

### Embodiment 1

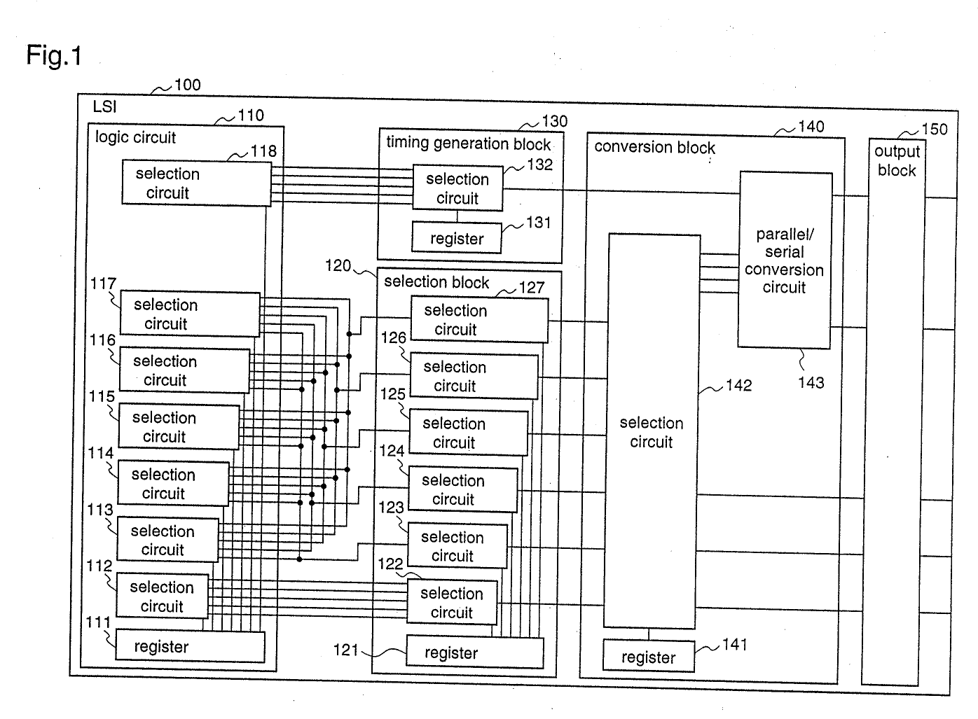

A debug circuit according to a first embodiment of the present invention will be described with reference to FIG. 1.

FIG. 1 is a block diagram illustrating a structure of a debug circuit according to the first embodiment.

In FIG. 1, an LSI 100 including a debug circuit according to the present invention comprises a logic circuit 110 that implements a main function of the LSI, a selection block 120 for selecting predetermined signals from signal groups that are outputted from the logic circuit 110, a timing generation block 130 for selecting a predetermined reference signal from a reference signal group that is outputted from the logic circuit 110, a conversion block 140 for converting parallel data that are inputted by the selection block 120 into serial data in a timing that is outputted from the timing generation block 130, and an output block 150 for outputting a signal that is outputted from the conversion block 140 to outside the LSI.

The logic circuit 110 comprises a register 111 that is rewritable from outside the LSI, selection circuits 112 to 117 for selecting a predetermined signal group from plural timing signal groups or plural condition signal groups in the logic circuit 110, and a selection circuit 118 for selecting a predetermined signal group from plural reference signal groups in the logic circuit 110. Further, the selection block 120 comprises a register 121 that is rewritable from outside the LSI, and selection circuits 122 to 127 each selecting a predetermined signal from the signal group that is outputted from the logic circuit 110. The timing generation block 130 comprises a register 131 that is rewritable from outside the LSI, and a selection circuit 132 for selecting a predetermined reference signal from the reference signal group that is outputted from the logic circuit 110. Further, the conversion block 140 comprises a register 141 that is rewritable from outside the LSI, a selection circuit 142 for selecting predetermined signals from the signal group that is inputted by the selection block 120, and a parallel/serial conversion circuit 143 for converting the parallel data that are outputted from the selection circuit 142 into serial data in the timing that is outputted from the timing generation block 130.

As described above, the debug circuit according to the first embodiment comprises the group of selection circuits 112 to 118 for selecting predetermined signal groups from plural timing signal groups, condition signal groups, and reference signal groups in the logic circuit 110, and the register 111, which are provided within the logic circuit of the LSI, the selection block 120 including the group of selection circuits 122 to 127 and the register 121, the timing generation block 130 including the selection circuit 132 and the register 131, the conversion block 140 including the register 141, the selection circuit 142, and the parallel/serial conversion circuit 143, and the output block 150.

Next, the operation of the debug circuit according to the first embodiment, which is constructed as described above, will be described in detail with reference to FIG. 1.

The logic circuit 110 is a circuit that implements the main function of the LSI 100. At designing the LSI, in preparation for a malfunction of the logic circuit 110, the designer of the LSI previously makes selectable plural internal timing or condition signals of the logic circuit 110, which are supposed to be effective in analyzing the malfunction and finding the cause thereof and, when a malfunction occurs, the designer connects these signals to the group of selection circuits 122 to 127 in the selection block 120. Further, the designer previously makes selectable plural reference signals for capturing the plural internal timing or condition signals which are supposed to be effective in finding the cause, and connects these reference signals to the selection circuit 132 of the timing generation block 130.

The operation of the common logic circuit is decided according to plural operation conditions, and plural timing or condition signals, and there are numberless combinations of the operation conditions and the timing or condition signals. However, since the designer of the logic circuit of the LSI performs verification of the circuit under these numberless operation conditions for a limited time by verifying the circuit in some representative operations, a malfunction may occur when there are operation conditions which are not supposed by the designer of the logic circuit of the LSI. The occurrence of such malfunction becomes more pronounced as the circuit scale of the LSI is larger, because the operation of the LSI becomes more complicated accordingly.

To solve this problem, in the first embodiment, the group of selection circuits 112 to 118 and the register 111 that is rewritable from outside the LSI are also provided in the logic circuit 110, and a group of output signals from the selection circuits are made selectable by decoding their values in accordance with a value of the register 111 that is rewritable from outside the LSI, thereby enabling to efficiently select more signals. For example, it is possible to provide a selection circuit for each function block of the logic circuit 110 or for each designer of the logic circuit 110, thereby making selectable plural timing or condition signals which are connected to the selection block 120, and plural reference signals which are connected to the timing generation block 130, for each function block or for each designer in the logic circuit 110, resulting in an improves the efficiency at the debugging.

In this first embodiment, to connect the plural timing or condition signals to the group of selection circuits 122 to 127 in the selection block 120, the outputs of the selection circuit 112 are connected to the input of the selection circuit 122, and respective outputs of the selection circuits 113 to 117 are connected to the inputs of the selection circuit 123 to 127. However, it is possible to realize a debug circuit by connecting the plural timing or condition signals to the group of selection circuits 122 to 127 in the selection block 120 in any connection manner.

The group of the selection circuits 122 to 127 in the selection block 120 can select the output signals from the respective selection circuits by decoding their values in accordance with a value of the register 121 that is rewritable from outside the LSI, and connect the selected signals to the conversion block 140.

Further, the plural reference signals outputted from the selection circuit 118 are connected to the selection circuit 132 in the timing generation block 130. The selection circuit 132 selects one of the output signals from the selection circuit 118 by decoding the value of the signal in accordance with a value of the register 131 that is rewritable from outside the LSI, and outputs the selected signal to the conversion block 140.

In the conversion block 140, the parallel/serial conversion circuit 143 latches signals that are selected by the selection circuit 142 from among the output signals from the group of selection circuits 122 to 127 in the selection block 120 using the output signal from the selection circuit 132 of the timing generation block 130, and converts the latched data into serial data in a specific order, thereby outputting the serial data to the output block 150. In order to facilitate an analysis at the debugging, it is also possible to output a strobe signal in synchronization with the data when this data is transmitted to the output block 150. Further, when the data is transmitted to the output block 150, it is possible to add a previously-decided reference signal at the front, or the back, or both of the front and the back of the transmission data. Thereby, it becomes possible to easily judge an effective range of the transmission data.

Further, in the conversion block 140, it is possible that the selection circuit 142 selects signals that change at higher speeds and signals that change at lower speed from among the output signals from the group of selection circuits 122 to 127 in the selection block 120, and inputs the signals that change at lower speeds to the parallel/serial conversion circuit 143 to be subjected to the parallel/serial conversion, while outputting the signals that change at higher speeds to the output block 150 as they are. By doing so, it becomes possible to observe plural states in the LSI using fewer output signals, by separating these signals into signals for debugging the detailed timing and signals for debugging the conditions. Further, it is also possible that the selection circuit 142 selects the output signals from the group of the selection circuits 122 to 127 in the selection block 120 to be divided into signals which are outputted to the parallel/serial conversion circuit 143 and signals which are outputted directly to the output block 150, by decoding values of the output signals in accordance with a value of the register 141 that is rewritable from outside the LSI.

The output block 150 outputs the data or the strobe signal outputted from the conversion block 140 to outside the LSI 100. Here, the output block 150 is not limited to the one that employs an external output pin as a debug-dedicated pin, and the output block may include a register (not shown) which is rewritable from outside the LSI, and output the data or strobe signal by multiplexing the same into the existing pin of the LSI 100, according to the value of the register.

Then, debugging is performed by observing the data or the strobe signal that is outputted from the output block 150 using a measuring device such as a logic analyzer. The debugging is performed by successively changing the values that are written in the registers 111, 121, 131, and 141, which are rewritable from outside the LSI, until a problematic internal timing signal or condition signal, i.e., a signal that causes the malfunction is found. Thereby, it is possible to easily implement the debugging of the malfunction of the internal timing signal or condition signal of the LSI 100.

As described above, the debug circuit according to the first embodiment comprises the group of selection circuits 112 to 118 for selecting internal signals of the logic circuit and the register 111 that is rewritable from outside the LSI, which are provided within the logic circuit of the LSI, the selection block 120 including the group of selection circuits 122 to 127 for selecting output signals from the group of the selection circuits 112 to 117 and the register 121 that is rewritable from outside the LSI, the timing generation block 130 including the selection circuit 132 for selecting an output signal from the output signals of the selection circuit 118 and the register 131 that is rewritable from outside the LSI, the conversion block 140 including the selection circuit 142 for selecting the output signals from the group of selection circuits 122 to 127, the parallel/serial conversion circuit 143 for converting the output signals from the selection circuit 142, and the register 141 that is rewritable from outside the LSI, and the output block 150 for outputting the output signal from the conversion block 140 to outside the LSI. Therefore, it is possible to efficiently select plural internal timing signals, condition signals, and reference signals in the logic circuit to improve the efficiency at the debugging and, at the same time, observe quite many internal signals in the logic circuit using fewer external pins by performing the parallel/serial conversion.

Further, by outputting the output signal with adding a reference signal or outputting the strobe signal in synchronization with the output signal, it is possible to easily judge an effective range of transmission data.

Further, since the conversion block 140 is provided with the selection circuit 142, for example, that selects signals changing at lower speeds as parallel/serial conversion signals, and selecting the other signals as signals that are outputted directly to outside the LSI, it is possible to observe plural conditions in the LSI using fewer output signals, with dividing these signals into signals for debugging detailed timing and signals for debugging the condition.

Further, since the logical circuit 110, the selection block 120, the timing generation block 130, and the conversion block 140 are provided with the registers 111, 121, 131 and 141 that are rewritable from outside the LSI, respectively, it is possible to freely change the output signals from these circuits or blocks by decoding the values that are held in the registers 111, 121, 131 and 141 even when the LSI is operating.

Further, by forming the external output pin of the output block 150 according to the first embodiment using a dedicated output pin of the LSI, it is possible to perform the debugging without any contrivance even on a board on which the LSI is mounted. In addition, when a register that is rewritable from outside the LSI is provided in the output block 150, the signals can be outputted using the existing output terminal of the LSI by decoding the value that is held in the register. Accordingly, it becomes possible to perform the debugging without providing a terminal that is designed specifically for debugging, thereby eliminating external pins that are dedicated for the debugging.

### Embodiment 2

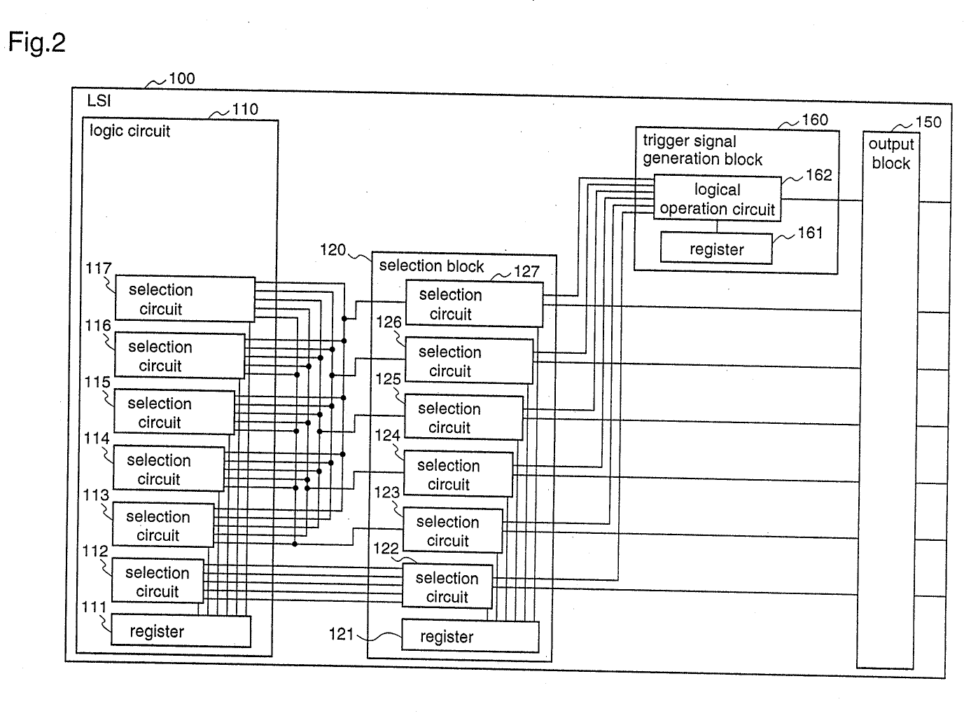

A debug circuit according to a second embodiment of the present invention will be described with reference to FIG. 2.

FIG. 2 is a block diagram illustrating a debug circuit according to the second embodiment.

In FIG. 2, an LSI 100 including a debug circuit according to the present invention comprises a logic circuit 110 that implements the main function of the LSI, a selection block 120 for selecting predetermined signals from groups of signals which are outputted from the logic circuit 110, a trigger signal generation block 160 for generating a trigger signal by performing a logical operation to data that are inputted from the selection block 120, and an output block 150 for outputting the signals that are outputted from the selection block 120 and the trigger signal generation block 160 to outside the LSI. In the debug circuit according to the second embodiment, the components other than the trigger signal generation block 160 are the same as those in the above-mentioned debug circuit according to the first embodiment, and are denoted by the same reference numerals.

The trigger signal generation block 160 comprises a register 161 that is rewritable from outside the LSI, and a logical operation circuit 162 which performs a logical operation to data that are inputted from the selection block 120.

Next, the operation of the debug circuit according to the second embodiment, which is constructed as described above, will be described in detail with reference to FIG. 2.

The logical circuit 110 is a circuit that implements the main function of the LSI 100. At the designing of the LSI, in preparation of a malfunction of the logic circuit 110, the designer of the LSI previously makes selectable plural internal timing or condition signals in the logic circuit 110, which are supposed to be effective in analyzing the malfunction and finding the cause thereof and, when a malfunction occurs, the designer connects these signals to the group of selection circuits 122 to 127 of the selection block 120.

The operation of the common logic circuit is decided according to plural operation conditions and plural timing or condition signals, and there are numberless combinations of the operation conditions and the timing or condition signals. However, as the designer of the logic circuit of the LSI performs verification of the logic circuit under these numberless operation conditions for a limited time by verifying the circuit in some representative operations, a malfunction may occur when there are operation conditions that are not supposed by the designer of the logic circuit of the LSI. The occurrence of such malfunction becomes more pronounced as the circuit scale of the LSI is larger, because the operation of the LSI becomes complicated accordingly.

To solve this problem, in this second embodiment, the group of selection circuits 112 to 117 and the register 111 that is rewritable from outside the LSI are also provided in the logic circuit 110, and a group of output signals from the respective selection circuits are made selectable by decoding values of the signals in accordance with the value of the register 111, whereby it becomes possible to efficiently select a larger number of signals. For example, when a selection circuit is provided for each function block in the logic circuit 110 or for each designer of the logic circuit 110, it becomes possible to select plural timing or condition signals which are to be connected to the selection block 120 for each function block in the logic circuit 110 or for each designer, thereby improving the efficiency at the debugging.

Further, in this second embodiment, to connect the plural timing or condition signals to the group of selection circuits 122 to 127 in the selection block 120, the outputs of the selection circuit 112 are connected to the input of the selection circuit 122, and the respective outputs of the selection circuits 113 to 117 are connected to the inputs of the selection circuit 123 to 127. However, it is possible to realize a debug circuit by connecting these signals to the group of selection circuits 122 to 127 in the selection block 120 in any connecting manner. The group of selection circuits 122 to 127 select output signals of the respective selection circuits by decoding their values in accordance with the value of the register 121 that is rewritable from outside the LSI, and connects the selected signals to the trigger signal generation block 160 or the output block 150. Here, to facilitate the debugging, it is possible that the selection block 120 is provided with plural registers that are rewritable from outside the LSI, to enable the group of selection circuits 122 to 127 in the selection block 120 to output plural output signals, whereby signals that are different from the plural signals which are inputted to the trigger signal generation block 160 can be outputted to the output block 150, by decoding values that are held in the plural registers.

In the trigger signal generation block 160, the plural timing or condition signals which are outputted from the selection block 120 are inputted to the logical operation circuit 162. The logical operation circuit 162 performs a logical operation to the inputted plural timing or condition signals according to a previously decided logical expression, by decoding the values of the signals in accordance with a value of the register 161 that is rewritable from outside the LSI. For example, when assuming that the signals which are inputted to the logical operation circuit 162 are A, B, C, D and E, and the value of the register 161 can be set at a range from 0 to 7 and when logical expressions, such as “A & B” when the value of the register 161 is 0, “A & B & C” when the value of the register 161 is 1, “A & B & C & D” when the value of the register 161 is 2, “A & B & C & D & E” when the value of the register 161 is 3, “A or B” when the value of the register 161 is 4, “A or B or C” when the value of the register 161 is 5, “A or B or C or D” when the value of the register 161 is 6, and “A or B or C or D or E” when the value of the register 161 is 7 are previously designed in the logical operation circuit 162, it is possible to input desired signals to the logical operation circuit 162 by changing the values of the registers 111 and 121 for the selection circuits, thereby easily generating a trigger signal that is required for the debugging. Here, the trigger signal that is generated by the logical operation is inputted to the output block 150, and outputted to outside the LSI.

The output block 150 outputs the trigger signal that is outputted from the trigger signal generation block 160 and the plural timing or condition signals that are outputted from the selection block 120, to outside the LSI 100. Here, the output block 150 is not limited to the one which employs an external output pin as a debug-dedicated pin, and it can include a register (not shown) which is rewritable from outside the LSI, thereby outputting a trigger signal or plural timing or condition signals by multiplexing the same on the existing pin of the LSI 100 in accordance with the value of the register.

Thereafter, debugging is performed by observing the trigger signal or the plural timing or condition signals which are outputted from the output block 150, using a measuring device such as a logic analyzer. The debugging is performed by successively changing values that are written in the registers 111, 121 and 161 that are rewritable from outside the LSI until the problematic internal timing signal or condition signal, i.e., the signal that causes a malfunction is found. Accordingly, it is possible to easily implement the debugging of the malfunction of the internal timing or condition signal in the LSI 100.

As described above, since the debug circuit according to the second embodiment includes the trigger signal generation block 160 that performs a logical operation to the plural signals which are outputted from the selection circuits 122 to 127 using the logical operation circuit 162 and outputs the trigger signal, it is possible to easily generate a trigger signal of a timing which is not supposed at the designing stage when the debugging is needed.

Further, as the trigger signal generation block 160 includes the register 161 that is rewritable from outside the LSI, it is possible to freely select one of preset logical operation patterns and perform the selected operation, by decoding the value that is held in the register 161, even when the LSI is operating, whereby it is possible to generate a trigger signal that is required for the debugging.

Further, as the logic circuit 110 and the selection block 120 also include the registers 111 and 121 that are rewritable from outside the LSI, it is possible to freely change the output signals of the circuit or block by decoding values that are held in the registers 111 and 121 even when the LSI is operating.

In addition, when an external output pin of the output block 150 according to the second embodiment is realized by a dedicated output pin of the LSI, it is possible to perform the debugging without any contrivance even on a board on which the LSI is mounted. Further, when a register that is rewritable from outside the LSI is provided in the output block 150, it is possible to output signals using the existing output terminal of the LSI by decoding the value that is held in the register. Accordingly, it becomes possible to perform the debugging without providing a terminal that is designed specifically for debugging, thereby eliminating the external pins that are dedicated for the debugging.

### Embodiment 3

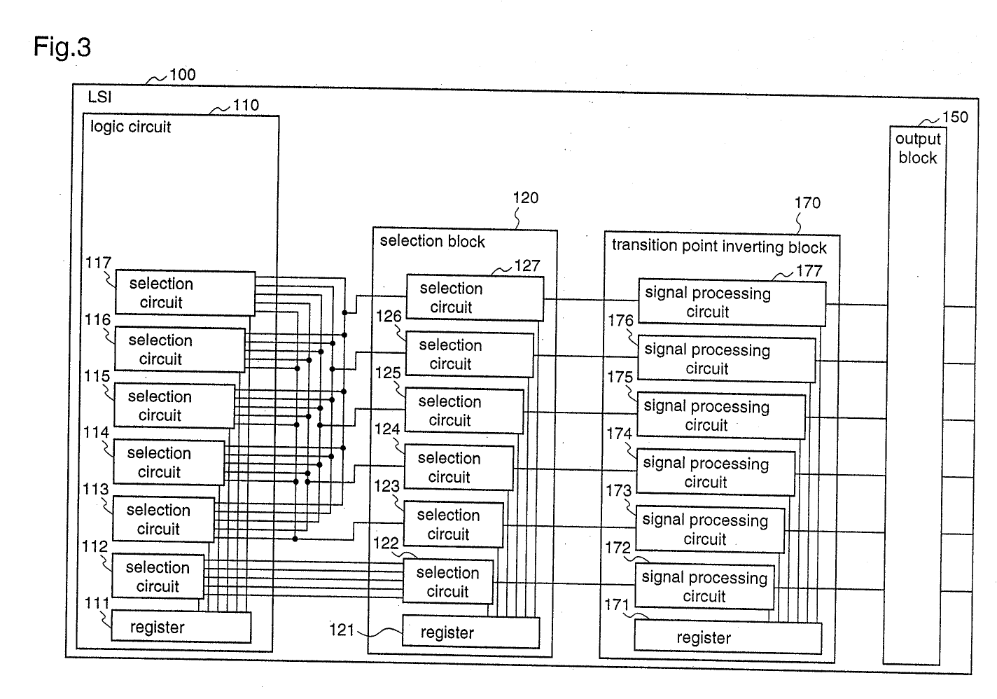

A debug circuit according to a third embodiment of the present invention will be described with reference to FIG. 3.

FIG. 3 is a block diagram illustrating a structure of the debug circuit according to the third embodiment.

In FIG. 3, a LSI 100 including a debug circuit according to the present invention comprises a logic circuit 110 for implementing the main function of the LSI, a selection block 120 for selecting predetermined signals from groups of signals that are outputted from the logic circuit 110, a transition point inverting block 170 for detecting transition points of plural timing or condition signals that are outputted from the selection block 120 to perform signal processing, and an output block 150 for outputting the signals that are outputted from the transition point inverting block 170, to outside the LSI. In the debug circuit according to the third embodiment, the components other than the transition point inverting block 170 are the same as those of the debug circuit according to the first embodiment, and they are denoted by the same reference numerals.

The transition point inverting block 170 comprises a register 171 that is rewritable from outside the LSI, and signal processing circuits 172 to 177 for detecting transition points of the signals that are outputted from the group of the selection circuits 122 to 127 in the selection block 120, thereby performing the signal processing.

Next, the operation of the debug circuit according to the third embodiment, which is constructed as described above, will be described in detail with reference to FIG. 3.

The logic circuit 110 is a circuit that implements the main function of the LSI 100. At the designing of the LSI, in preparation of a malfunction of the logic circuit 110, the designer of the LSI previously makes selectable plural internal timing signals or condition signals of the logic circuit 110, which are supposed to be effective in analyzing a malfunction and finding the cause thereof and, when a malfunction occurs, the designer connects these signals to the group of selection circuits 122 to 127 in the selection block 120.

The operation of the common logic circuit is decided according to plural operation conditions and plural timing or condition signals, and there are numberless combinations of the operation conditions and the timing or condition signals. However, as the designer of the logic circuit of the LSI performs verification of the circuit under these numberless operation conditions for a limited time by verifying the circuit in some representative operations, a malfunction may occur when there are operation conditions that are not supposed by the designer of the logic circuit of the LSI. The occurrence of such malfunction becomes more pronounced as the circuit scale of the LSI becomes larger because the operation of the LSI becomes more complicated accordingly.

To solve this problem, in the third embodiment, the group of selection circuits 112 to 117 and the register 111 that is rewritable from outside the LSI are also provided in the logic circuit 110, and the group of output signals from the respective selection circuits are made selectable by decoding the values of the signals in accordance with the value of the register 111, whereby it becomes possible to select a larger number of signals with efficiency. For example, when a selection circuit is provided for each function block of the logic circuit 110 or for each designer of the logic circuit 110, it is possible to make selectable plural timing or condition signals that are connected to the selection block 120 for each function block in the logic circuit 110 or for each designer, thereby improving the efficiency at the debugging.

In addition, in this third embodiment, to connect plural timing or condition signals to the group of selection circuits 122 to 127 in the selection block 120, the outputs of the selection circuit 112 are connected to the input of the selection circuit 122, and respective outputs of the selection circuits 113 to 117 are connected to the inputs of the selection circuits 123 to 127. However, it is possible to realize a debug circuit even by connecting these signals to the group of the selection circuits 122 to 127 of the selection block 120 in any connecting manner. The group of the selection circuits 122 to 127 selects the output signals of the respective selection circuits by decoding their values in accordance with the value of the register 121 which is rewritable from outside the LSI, and connects the selected signals to the transition point inverting block 170.

In the transition point inverting block 170, the signals that are outputted from the group of the selection circuits 122 to 127 of the selection block 120 are inputted to the corresponding signal processing circuits of the group of signal processing circuits 172 to 177. The group of signal processing circuits 172 to 177 which receive the inputted signals detects transition points of the signals at a rising edge or a falling edge, or both of the edges, by decoding values of the signals according to the value of the register 171 that is rewritable from outside the LSI, inverts the signals, and outputs the inverted signals to the output block 150. These setting can be performed for each signal processing circuit using the register 171 that is rewritable from outside the LSI. It is also possible to individually switch their functions ON or OFF.

The output block 150 outputs the signals that are outputted from the transition point inverting block 170 to outside the LSI 100. Here, the output block 150 is not limited to the one that employs an external output pin as a debug-dedicated pin, and it is also possible that the output block 150 includes a register (not shown) which is rewritable from outside the LSI, and outputs signals by multiplexing the same on the existing pin of the LSI 100 in accordance with the value of the register.

Thereafter, debugging is performed by observing the signals that are outputted from the output block 150 using a measuring device such as a logic analyzer. The debugging is performed by successively changing a value that is rewritten in the registers 111, 121, and 171 that are rewritable from outside the LSI, until the problematic internal timing or condition signal, i.e., the signal which causes the malfunction is found. Thereby, it is possible to easily implement the debugging of the malfunction of the internal timing or condition signal in the LSI.

As described above, the debug circuit according to the third embodiment includes the transition point inverting block 170 that detects respective transition points of the plural signals that are selected in the selection block 120 using the group of the corresponding signal processing circuits 172 to 177, thereby inverting the signals. Therefore, it is possible to relatively easily capture the signals that change at high speeds and observe also high-speed signals, thereby greatly improving the debug efficiency.

Further, by providing the register 171 that is rewritable from outside the LSI in the transition point inverting block 170 and decoding the value that is held in the register 171, it is possible to freely select one of the rising edge, the falling edge, and both of the edges as an edge to be analyzed also during the operation of the LSI, thereby detecting the transition point of the signal. It is also possible to switch the execution of the inverting function ON or OFF by decoding the value that is held in the register 171, thereby selecting whether there is a need of analyzing the transition point of each signal or not.

In addition, by providing the registers 111 and 121 that are rewritable from outside the LSI also in the logic circuit 110 and the selection block 120, respectively, it is possible to freely change the output signals from the logic circuit or the selection block also during the operation of the LSI by decoding the values that are held in the registers 111 and 121, respectively.

Further, by realizing an external output pin of the output block 150 according to the third embodiment by a dedicated output pin of the LSI, it is possible to perform the debugging without any contrivance even on a board on which the LSI is mounted. In addition, when a register that is rewritable from outside the LSI is provided in the output block 150, it is also possible to output the signals using the existing output terminal of the LSI by decoding a value that is held in the register. Accordingly, it becomes possible to perform the debugging without providing a terminal that is designed specifically for debugging, thereby eliminating the external pins that are dedicated for the debugging.

### Embodiment 4

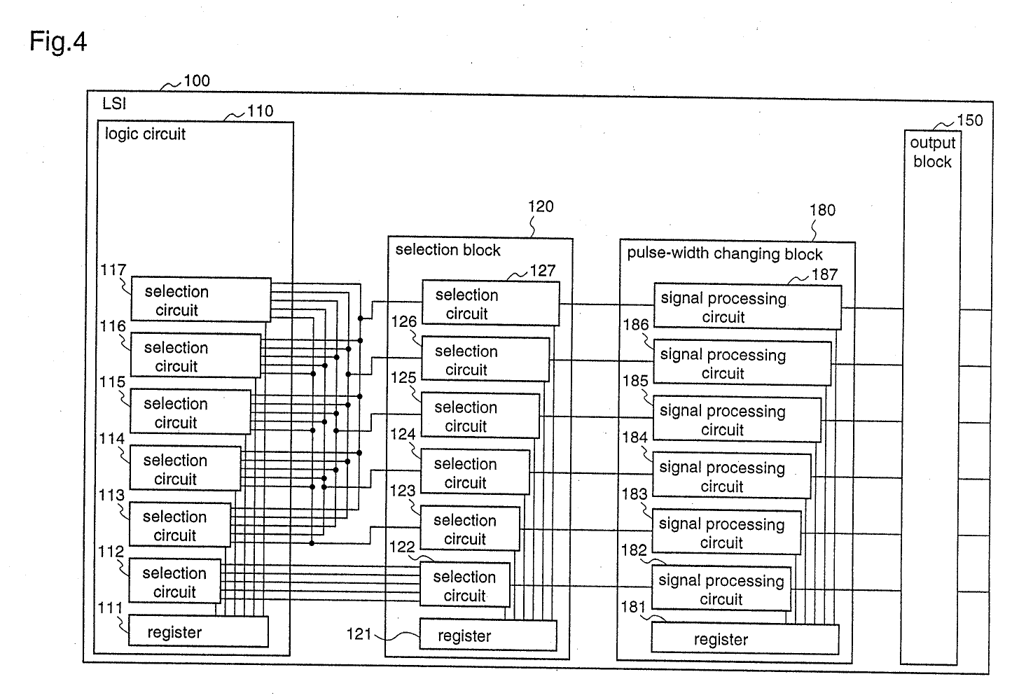

A debug circuit according to a fourth embodiment of the present invention will be described with reference to FIG. 4.

FIG. 4 is a block diagram illustrating a structure of the debug circuit according to the fourth embodiment.

In FIG. 4, an LSI 100 including a debug circuit according to the present invention comprises a logic circuit 110 for implementing the main function of the LSI, a selection block 120 for selecting predetermined signals from groups of signals that are outputted from the logic circuit 110, a pulse-width changing block 180 for detecting transition points of the plural timing or condition signals that are outputted from the selection block 120 to perform signal processing, and an output block 150 for outputting the signals that are outputted from the pulse-width changing block 180 to outside the LSI. In the debug circuit according to the fourth embodiment, the components other than the pulse-width changing block 180 are the same as those of the debug circuit according to the first embodiment, and thus are denoted by the same references.

The pulse-width changing block 180 comprises a register 181 that is rewritable from outside the LSI, and a group of signal processing circuits 182 to 187 for detecting transition points of the signals outputted from the group of selection circuits 122 to 127 in the selection block 120, thereby to perform signal processing.

Next, the operation of the debug circuit according to the fourth embodiment, which is constructed as described above, will be described in detail with reference to FIG. 4.

The logic circuit 110 is a circuit that implements the main function of the LSI 100. At the designing of the LSI, in preparation of a malfunction of the logic circuit 110, the designer of the LSI previously makes selectable plural internal timing signals or condition signals in the logic circuit 110, which are supposed to be effective in analyzing the malfunction and finding the cause thereof and, when a malfunction occurs, the designer connects these signals to the group of selection circuits 122 to 127 in the selection block 120.

The operation of the common logic circuit is decided according to plural operation conditions and plural timing or condition signals, and there are numberless combinations of the operation conditions and the timing or condition signals. However, as the designer of the logic circuit of the LSI performs verification of the circuit in these numberless combinations for a limited time by verifying the circuit in some representative operations, a malfunction may occur when there are operation conditions that are not supposed by the designer of the logic circuit of the LSI. The occurrence of such malfunction becomes more pronounced as the circuit scale of the LSI becomes larger because the operation of the LSI becomes more complicated accordingly.

To solve this problem, in this fourth embodiment, the group of selection circuits 112 to 117, and the register 111 that is rewritable from outside the LSI are also provided in the logic circuit 110, and the group of output signals from the respective selection circuits are made selectable by decoding the values of the signals in accordance with the value of the register 111, whereby it becomes possible to select a larger number of signals with efficiency. For example, it is possible to provide a selection circuit for each function block in the logic circuit 110 or for each designer of the logic circuit 110, thereby enabling to select plural timing or condition signals that are to be connected to the selection block 120 for each function block in the logic circuit 110 or each designer, and enhancing the efficiency at the debugging.

Further, in this fourth embodiment, to connect the plural timing or condition signals to the group of selection circuits 122 to 127 in the selection block 120, the outputs of the selection circuit 112 are connected to the input of the selection circuit 122, and the respective outputs of the selection circuits 113 to 117 are connected to the inputs of the selection circuits 123 to 127, while it is possible to realize a debug circuit by connecting these signals to the group of the selection circuits 122 to 127 of the selection block 120 in any connecting manner. The group of selection circuits 122 to 127 select output signals of the respective selection circuits of the logic circuit 110, by decoding the values of the signals in accordance with the value of the register 121 that is rewritable from outside the LSI, thereby to connect these selected signals to the pulse-width changing block 180.

The pulse-width changing block 180 inputs the signals that are outputted from the group of selection circuits 122 to 127 of the selection block 120 to the corresponding signal processing circuits 182 to 187. The group of signal processing circuits 182 to 187 which receives the inputted signals decodes the values of these signals in accordance with the value of the register 181 that is rewritable from outside the LSI, to detect transition points of the signals at a rising edge, a falling edge, or both of the edges, changes the pulse width, and outputs the signals to the output block 150. Such setting can be performed for the respective signal processing circuits using the register 181 that is rewritable from outside the LSI, and it is also possible to individually switch their functions ON or OFF. It is also possible to set the change amount of the pulse width.

The output block 150 outputs the signals that are outputted from the pulse-width changing block 180 to outside the LSI 100. Here, the output block 150 is not limited to the one that employs an external output pin as a debug-dedicated pin, and it can be provided with a register (not shown) which is rewritable from outside the LSI, thereby outputting the signals in accordance with the value of the register by multiplexing the same on the existing pin of the LSI.

Thereafter, debugging is performed by observing the signals that are outputted from the output block 150 using a measuring device such as a logic analyzer. The debugging is performed by successively changing values that are written in the registers 111, 121, and 181 which are rewritable from outside the LSI, until a problematic internal timing or condition signal, i.e., a signal that causes a malfunction is found. Thereby, the debugging of the malfunction of the internal timing signal or condition signal of the LSI 100 can be easily realized.

As described above, the debug circuit according to the fourth embodiment includes the pulse-width changing block 180 that detects respective transition points of the plural signals which are selected in the selection block 120 using the group of corresponding signal processing circuits 182 to 187, and enlarges the pulse width of the signals. Therefore, it is possible to relatively easily capture signals that change at high speeds, whereby it is possible to observe also high-speed signals, and accordingly greatly enhance the debug efficiency.

Further, by providing the register 181 that is rewritable from outside the LSI in the pulse-width changing block 180 and decoding a value that is held in the register 181, it is possible to freely select one of the rising edge, the falling edge, and both of the edges as an edge to be analyzed also when the LSI is operating, thereby detecting the transition point of the signals. In addition, by decoding the value that is held in the register 181, it becomes possible to freely select the change amount of the pulse width, thereby enabling to perform signal processing corresponding to the resolution of the measuring device that is used for the analysis. Further, by decoding the value that is held in the register, it is possible to switch the execution of the pulse-width changing function ON or OFF, thereby to select whether there is a need of analyzing the respective transition points of the signals or not.

Further, by providing the registers 111 and 121 that are rewritable from outside the LSI also in the logic circuit 110 and the selection block 120, respectively, it is possible to change the output signals from the logic circuit or the selection block also when the LSI is operating, by decoding values that are held in the registers 111 and 121.

Further, by realizing the external output pin of the output block 150 according to the fourth embodiment using a dedicated output pin of the LSI, it is possible to perform the debugging without any contrivance even on a board on which the LSI is mounted. In addition, when a register that is rewritable from outside the LSI is provided in the output block 150, it is also possible to output the signals using the existing output terminal of the LSI by decoding a value that is held in the register. Accordingly, it becomes possible to perform the debugging without providing a terminal that is designed specifically for debugging, thereby eliminating the external pins that are dedicated for the debugging.

### Embodiment 5

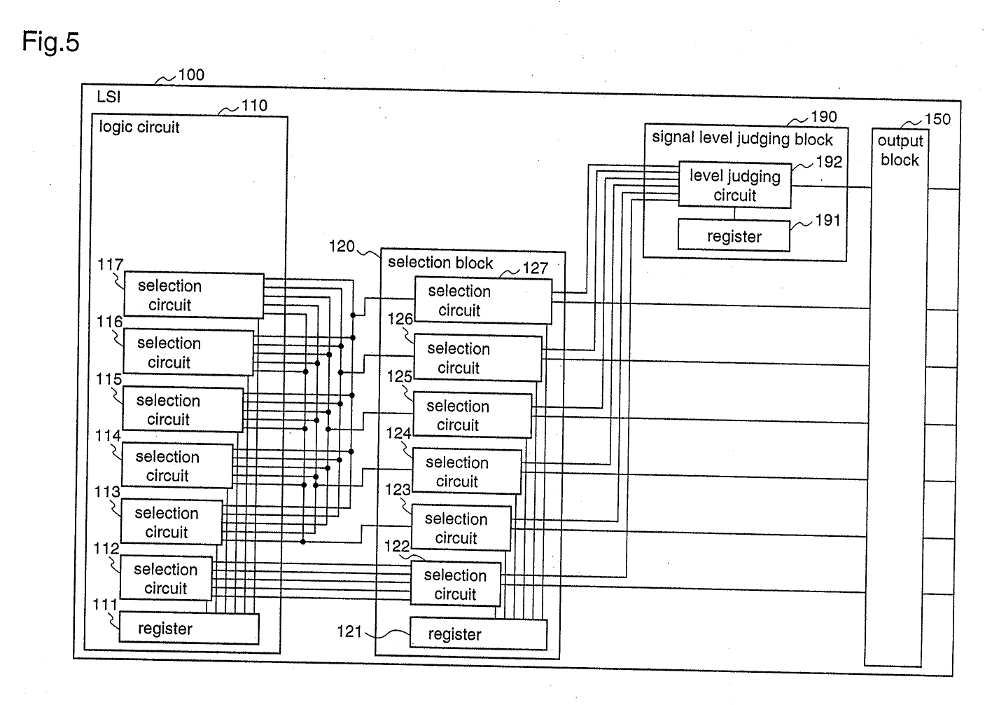

A debug circuit according to a fifth embodiment of the present invention will be described with reference to FIG. 5.

FIG. 5 is a block diagram illustrating a structure of the debug circuit according to the fifth embodiment.

In FIG. 5, an LSI 100 including a debug circuit according to the present invention comprises a logic circuit 110 for implementing the main function of the LSI, a selection block 120 for selecting predetermined signals from groups of signals that are outputted from the logic circuit 110, a signal level judging block 190 for comparing the levels of the signals that are inputted from the selection block 120 with set values, and an output block 150 for outputting signals that are outputted from the selection block 120 and the signal level judging block 190, to outside the LSI. In the debug circuit according to the fifth embodiment, the components other then the signal level judging block 190 are the same as those in the debug circuit according to the first embodiment, and are denoted by the same reference numerals.

The signal level judging block 190 comprises a register 191 that is rewritable from outside the LSI, and a level judging circuit 192 for comparing the levels of the signals that are inputted from the selection block 120 with values that are set in the register 191.

Next, the operation of the debug circuit according to the fifth embodiment, which is constructed as described above, will be described in detail with reference to FIG. 5.

The logic circuit 110 is a circuit that implements the main function of the LSI 100. At the designing of the LSI, in preparation of a malfunction of the logic circuit 110, the designer of the LSI previously makes selectable plural internal timing or condition signals in the logic circuit 110, which are supposed to be effective in analyzing of the malfunction and finding the cause thereof and, when a malfunction occurs, the designer connects these signals to a group of selection circuits 122 to 127 in the selection block 120.

The operation of the common logic circuit is decided according to plural operation conditions and plural timing or condition signals, and there are numberless combinations of the operation conditions and timing or condition signals. However, since the designer of the logic circuit of the LSI performs verification of the circuit under these numberless operation conditions for a limited time, by verifying the circuit in some representative operations, a malfunction may occurs when there are operation conditions that are not supposed by the designer of the logic circuit of the LSI. The occurrence of such malfunction becomes more pronounced as the circuit scale of the LSI becomes larger, because the operation of the LSI becomes more complicated accordingly.

To solve this problem, in this fifth embodiment, the group of selection circuits 112 to 117 and the register 111 that is rewritable from outside the LSI are also provided in the logic circuit 110, and groups of output signals from the selection circuits are made selectable by decoding values of the signals in accordance with the value of the register 111, thereby selecting more signals with efficiency. For example, when a selection circuit is provided for each function block of the logic circuit 110 or for each designer of the logic circuit 110, it becomes possible to select plural timing or condition signals that are connected to the selection block 120 for each function block or for each designer in the logic circuit 110, thereby enhancing the efficiency at the debugging.

Further, in this fifth embodiment, to connect the plural timing or condition signals to the group of selection circuits 122 to 127 in the selection block 120, the outputs of the selection circuit 112 are connected to the input of the selection circuit 122, and the respective outputs of the selection circuits 113 to 117 are connected to the inputs of the selection circuits 123 to 127, while it is possible to realize a debug circuit by connecting these signals to the group of selection circuits 122 to 127 of the selection block 120 in any connecting manner. The group of selection circuits 122 to 127 select output signals from the selection circuits of the logical circuit 110 by decoding values of the signals in accordance with the value of the register 121 that is rewritable from outside the LSI, and are connected to the signal level judging block 190 or the output block 150. In order to facilitate the debugging, it is also possible to output different signals from the plural signals that are inputted to the signal level judging block 190, by providing plural registers that are rewritable from outside the LSI in the selection block 120, to enable the group of selection circuits 122 to 127 in the selection block 120 to output plural output signals, and by decoding values that are held in the plural registers.

In the signal level judging block 190, plural timing or condition signals that are outputted from the selection block 120 are inputted to the level judging circuit 192. The level judging circuit 192 compares values that are set by the register 191 that is rewritable from outside the LSI and the levels of the inputted plural timing or condition signals with each other, and outputs a level judgement result signal to the output block 150. In this case, “1” is outputted when values of the register 191 corresponding to the respective outputs of the selection circuits 122 to 127 and the output values from the selection circuits 122 to 127 are all the same, while in other cases “0” is outputted as the level judgement result signal to the output block 150.

More specifically, when the value of the register is “101101” (corresponding to the selection circuits 122, 123, 124, 125, 126 and 127, respectively, from the LSB), and when the output of the selection circuit 122 is “1”, the output of the selection circuit 123 is “1”, the output of the selection circuit 124 is “0”, the output of the selection circuit 125 is “1”, the output of the selection circuit 126 is “1”, and the output of the selection circuit 127 is “0”, “0” is outputted to the output block 150 as the level judgement result signal because the value of the register 191 and the output values of the selection circuits 122 to 127 are not the same.

Accordingly, it becomes possible to easily generate signals that are required for debugging by changing the values of the registers 111 and 121 to input desired signals to the level judging circuit 192, and changing the value of the register 191 at a desired value. The level judgement result signal that is obtained from the level judgement is inputted to the output block 150 and outputted to outside the LSI.

The output block 150 outputs the level judgement result signal that is outputted from the signal level judging block 190 and the plural timing or condition signals that are outputted from the selection block 120 to outside the LSI 100. Here, the output block 150 is not limited to the one that employs the external output pin as a debug-dedicated pin, and it can be provided with a register (not shown) that is rewritable from outside the LSI, and output a level judgement result signal or plural timing or condition signals by multiplexing the signal on the existing pin of the LSI 100 according to the value of the register.

Thereafter, debugging is performed by observing the level judgement result signal or the plural timing or condition signals that are outputted from the output block 150 using a measuring device such as a logic analyzer. The debugging is performed by successively changing values that are written in the registers 111, 121 and 191 that are rewritable from outside the LSI, until a problematic internal timing or condition signal, i.e., a signal that causes a malfunction is found. Accordingly, it is possible to easily realize debugging of a malfunction of the internal timing or condition signal of the LSI 100.

As described above, the debug circuit according to the fifth embodiment includes the signal level judging block 190 that compares values which are held in the register 191 that is rewritable from outside the LSI and the levels of the plural signals which are selected in the selection block 120 with each other, and outputs the result of the comparison to outside the LSI. Therefore, it is possible to detect abnormal conditions of plural signals on a bus such as a data bus or an address bus in the LSI using quite a few output terminals and, in addition, it is possible to freely change a comparison reference value by changing the value of the register even when the LSI is operating, thereby further enhancing the debug efficiency.

Further, by providing the registers 111 and 121 that are rewritable from outside the LSI also in the logic circuit 110 and the selection block 120, it becomes possible to freely change the output signals from the logic circuit or the selection block also when the LSI is operating, by decoding values that are held in the registers 111 and 121, respectively.

Further, by realizing an external output pin of the output block 150 according to the fifth embodiment with a dedicated output pin of the LSI, it is possible to perform the debugging without any contrivance even on a board on which the LSI is mounted. In addition, when a register that is rewritable from outside the LSI is provided in the output block 150, it is also possible to output signals using the existing output terminal of the LSI by decoding a value that is held in the register. Accordingly, it becomes possible to perform the debugging without providing a terminal that is designed specifically for debugging, thereby eliminating the external pins which are dedicated for the debugging.

The debug circuit according to the present invention has an effect of checking internal timing or conditions that are outputted from the internal circuit of the LSI, which is mounted on a target apparatus, from outside the LSI and, at the evaluation of the apparatus, quickly finding an omission of debugging in the logical simulation at the verification of the LSI design, whereby it is possible to reduce the number of steps at the evaluation of the LSI and shorten the time taken to develop the LSI. This invention is also useful for a debug circuit that enables to analyze a potential bug that has not been detected at the evaluation of the LSI and may occur in actual use environments and, specially useful for a method of analyzing the timing of the logic circuit in the LSI at the malfunction of the logic circuit.

What is claimed is:

1. A debug circuit which debugs functions of an LSI including a logic circuit that realizes desired logic functions, comprising:
a selection block for selecting predetermined signals from plural timing signals or plural condition signals which are outputted from the logic circuit;
a signal conversion block for detecting transition points of the respective predetermined signals which are selected in the selection block, and processing the predetermined signals at the detected transition points to output the same; and
an output block for outputting the predetermined signals that are converted in the signal conversion block to the outside.

2. The debug circuit as defined in claim 1 wherein
the signal conversion block inverts the predetermined signals at the detected transition points to output the same.

3. The debug circuit as defined in claim 2 wherein
the signal conversion block includes a register that is rewritable from outside the LSI, and switches execution of the inverting function in the signal conversion block ON or OFF on the basis of a value of the register.

4. The debug circuit as defined in claim 1 wherein
the signal conversion block changes the pulse widths of the predetermined signals.

5. The debug circuit as defined in claim 4 wherein
the signal conversion block includes a register that is rewritable from outside the LSI, and changes the amount of change of the pulse width for each of the predetermined signals on the basis of a value of the register.

6. The debug circuit as defined in claim 4 wherein
the signal conversion block includes a register that is rewritable from outside the LSI, and switches execution of the pulse-width changing function in the signal conversion block ON or OFF on the basis of a value of the register.

7. The debug circuit as defined in claim 1 wherein
the signal conversion block includes a register that is rewritable from outside the LSI, and changes the type of an edge that is detected as the transition point for each of the predetermined signals that are selected in the selection block, on the basis of a value of the register.

8. The debug circuit as defined in claim 1 wherein
the selection block includes a register that is rewritable from outside the LSI, and performs the selection of the plural timing or condition signals which are outputted from the logic circuit, on the basis of a value of the register.

9. The debug circuit as defined in claim 1 wherein
the logic circuit includes
a register that is rewritable from outside the LSI, and
selection circuits for performing selection of plural timing signals, plural condition signals, or plural reference signals in accordance with a value of the register.

10. The debug circuit as defined in claim 1 wherein
the output block performs the outputting using a debug-dedicated terminal.

11. The debug circuit as defined in claim 1 wherein
the output block includes a register that is rewritable from outside the LSI, and
the output block performs the outputting using an existing output terminal of the LSI by decoding a value of the register.
